(19) United States
(12) Patent Application Publication
(10) Pub. No.: US 2025/0081738 A1
(43) Pub. Date: Mar. 6, 2025

(54) DISPLAY MOTHERBOARD, DISPLAY PANEL AND DISPLAY APPARATUS

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yingchang GAO, Beijing (CN); Jaeyoung LEE, Beijing (CN); Song HUANG, Beijing (CN); Yingqi YUAN, Beijing (CN)

(21) Appl. No.: 18/550,518

(22) PCT Filed: Oct. 11, 2022
(86) PCT No.: PCT/CN2022/124566

§ 371 Date: Sep. 14, 2023

(51) Int. Cl. H10K 59/122; H10K 59/40; H10K 59/80; H10K 59/88

(52) U.S. Cl. CPC H10K 59/122; H10K 59/40; H10K 59/879; H10K 59/88; H10K 59/874

(57) ABSTRACT

A display motherboard has display areas, peripheral areas and a cutting area. The display motherboard includes a substrate motherboard, virtual barriers disposed on the substrate motherboard and located in the cutting area, a first encapsulation layer located in a display area and a peripheral area surrounding the display area and spaced from the virtual barriers, and a first insulating layer disposed on a side of the first encapsulation layer away from the substrate motherboard. A virtual barrier includes a planarization layer block and a pixel definition layer block that are stacked, and the pixel definition layer block is farther away from the substrate motherboard the planarization layer block. The first insulating layer covers the virtual barriers, and is in contact with the pixel definition layer block. A material of the pixel definition layer block and a material of the first insulating layer each include a hydrophilic material.

### CROSS-REFERENCE TO RELATED APPLICATION

The present application is a national phase entry under 35 USC 371 of International Patent Application No. PCT/CN2022/124566, filed on Oct. 11, 2022, which is incorporated herein by reference in its entirety.

### TECHNICAL FIELD

The present disclosure relates to the field of display technologies, and in particular, to a display motherboard, a display panel and a display apparatus.

### BACKGROUND

Organic light-emitting diodes (OLEDs) have attracted much attention due to their advantages of self-luminescence, wide viewing angle, high contrast, fast response speed, low power consumption, and the like. Flexible multi-layer on cell (FMLOC) can further reduce the thickness of the display apparatus by integrating the touch layer in the display panel, which is conducive to the thinness of the display apparatus.

### SUMMARY

In an aspect, a display motherboard is provided. The display motherboard has a plurality of display areas, peripheral areas each surrounding a single display area, and a cutting area located on a side of the peripheral areas away from the respectively display areas. The display motherboard includes a substrate motherboard, virtual barriers, a first encapsulation layer and a first insulating layer. The virtual barriers are disposed on the substrate motherboard and in the cutting area. A virtual barrier includes a planarization layer block and a pixel definition layer block that are stacked, and the pixel definition layer block is farther away from the substrate motherboard than the planarization layer block. The first encapsulation layer is located in a display area and a peripheral area surrounding the display area and spaced from the virtual barriers. The first insulating layer is disposed on a side of the first encapsulation layer away from the substrate mother board, covers the virtual barriers, and in contact with the pixel definition layer block. A material of the pixel definition layer block and a material of the first insulating layer each include a hydrophilic material.

In some embodiments, the material of the first insulating layer includes silicon oxide and/or silicon oxynitride.

In some embodiments, the display motherboard further includes a second insulating layer. The second insulating layer is disposed on a side of the first insulating layer away from the substrate motherboard, covers the virtual barriers and is in contact with the first insulating layer. A material of the second insulating layer includes at least one of silicon oxide, silicon oxynitride and silicon nitride.

In some embodiments, both the first insulating layer and the second insulating layer are of a single-layer film structure. Both the material of the first insulating layer and the material of the second insulating layer include silicon oxynitride; or the material of the first insulating layer includes silicon oxynitride, and the material of the second insulating layer includes silicon nitride; or the material of the first insulating layer includes silicon oxide, and the material of the second insulating layer includes silicon nitride; or the material of the first insulating layer includes silicon oxide, and the material of the second insulating layer includes silicon oxynitride.

In some embodiments, the material of the first insulating layer includes silicon oxynitride or silicon oxide, and the material of the second insulating layer includes silicon nitride. A thickness of the first insulating layer is less than a thickness of the second insulating layer.

In some embodiments, the first encapsulation layer includes a first inorganic layer, an organic layer and a second inorganic layer that are stacked. A refractive index of the first insulating layer is smaller than a refractive index of the second inorganic layer, and a refractive index of the second insulating layer is greater than the refractive index of the first insulating layer.

In some embodiments, the first insulating layer is of a multi-layer film structure. In a direction perpendicular to the substrate motherboard and away from the substrate motherboard, multi-layer films included in the first insulating layer include a first sub-film and a second sub-film alternately stacked; a material of the first sub-film includes silicon oxide or silicon oxynitride.

In some embodiments, the material of the first sub-film includes silicon oxide, and a material of the second sub-film includes silicon nitride; or the material of the first sub-film includes silicon oxide, and the material of the second sub-film includes silicon oxynitride; or the material of the first sub-film includes silicon oxynitride, and the material of the second sub-film includes silicon nitride.

In some embodiments, the second insulating layer is of a multi-layer film structure. In the direction perpendicular to the substrate motherboard and away from the substrate motherboard, multi-layer films included in the second insulating layer include a third sub-film and a fourth sub-film alternately stacked; a material of the third sub-film includes silicon oxide or silicon oxynitride.

In some embodiments, a film in the multi-layer films included in the first insulating layer farthest from the substrate motherboard is the second sub-film. The material of the third sub-film includes silicon oxide, and a material of the fourth sub-film includes silicon oxynitride or silicon nitride. In a case where a material of the second sub-film includes silicon nitride, the material of the third sub-film includes silicon oxynitride, and the material of the fourth sub-film includes silicon nitride

In some embodiments, the first encapsulation layer includes a first inorganic layer, an organic layer and a second inorganic layer that are stacked. A refractive index of the first sub-film of the first insulating layer is smaller than a refractive index of the second inorganic layer, and a refractive index of the second sub-film of the first insulating layer is greater than the refractive index of the first sub-film of the first insulating layer. In a case where a film in the multi-layer films included in the first insulating layer farthest from the substrate motherboard is the first sub-film, the refractive index of the third sub-film is greater than the refractive index of the first sub-film, and the refractive index of the fourth sub-film is smaller than the refractive index of the third sub-film. In a case where a film in the multi-layer films included in the first insulating layer farthest from the substrate motherboard is the second sub-film, the refractive index of the third sub-film is smaller than the refractive index of the second sub-film, and the refractive index of the fourth sub-film is greater than the refractive index of the third sub-film.

In some embodiments, the display motherboard further includes an inorganic material stacked-layer, a first planarization layer, a second planarization layer, and a pixel definition layer that are sequentially arranged in a direction perpendicular to the substrate motherboard and away from the substrate motherboard; the pixel definition layer is closer to the substrate motherboard than the first encapsulation layer. The planarization layer block includes a first sub-block disposed in the first planarization layer and a second sub-block disposed in the second planarization layer; the pixel definition layer block is disposed in the pixel definition layer. An orthographic projection of the second sub-block on the substrate motherboard is located within an orthographic projection of the first sub-block on the substrate motherboard, and the pixel definition layer block covers a surface of the second sub-block away from the substrate motherboard and sidewalls of the second sub-block.

In some embodiments, the display motherboard further includes a first barrier, a second barrier and an anti-crack barrier. The first barrier is located in the peripheral area and surrounding the display area. The first barrier includes a third sub-block disposed in the second planarization layer and a fourth sub-block disposed in the pixel definition layer. An orthographic projection of the fourth sub-block on the substrate motherboard is within an orthographic projection of the third sub-block on the substrate motherboard. The second barrier is located in the peripheral area and on a side of the first barrier away from the display area. The second barrier includes a fifth sub-block disposed in the first planarization layer, a sixth sub-block disposed in the second planarization layer, and a seventh sub-block disposed in the pixel definition layer. On the substrate motherboard, an orthographic projection of the seventh sub-block is located within an orthographic projection of the sixth sub-block, and the orthographic projection of the sixth sub-block is located within an orthographic projection of the fifth sub-block. The anti-crack barrier is located in the peripheral area and on a side of the second barrier away from the first barrier, and the anti-crack barrier includes an eighth sub-block disposed in the first planarization layer.

The inorganic material stacked-layer includes a first groove located between the virtual barriers and the peripheral area, and a second groove located between two adjacent virtual barriers. The display motherboard further includes a first connecting portion and a second connecting portion. The first connecting portion is at least partially located in the first groove and connected to the eighth sub-block and the first sub-block. The second connecting portion is at least partially located in the second groove and connected to the first sub-blocks of two adjacent virtual barriers.

In some embodiments, the display motherboard further includes a first metal layer, a second metal layer, and a second encapsulation layer. The first metal layer is located between the first insulating layer and the second insulating layer. The second metal layer is located on a side of the second insulating layer away from the first encapsulation layer. The second encapsulation layer is located on a side of the second metal layer away from the first encapsulation layer.

One of the first metal layer and the second metal layer includes a plurality of first touch electrodes, a plurality of second touch electrodes and a plurality of connection portions, and another of the first metal layer and the second metal layer includes a plurality of bridge portions. Each connection portion is connected to two adjacent first touch electrodes, and each bridge portion is connected to two adjacent second touch electrodes through via holes. Alternatively, each connection portion is connected to two adjacent second touch electrodes, and each bridge portion is connected to two adjacent first touch electrodes through via holes.

In another aspect, a display panel is provided. The display panel has a display area and a peripheral area surrounding the display area. The display panel includes a substrate, a pixel definition layer, a first encapsulation layer and a first insulating layer. The pixel definition layer is disposed on the substrate, and a material of the pixel definition layer includes a hydrophilic material. The first encapsulation layer is disposed on a side of the pixel definition layer away from the substrate. The first insulating layer is disposed on a side of the first encapsulation layer away from the substrate, and the material of the first insulating layer includes a hydrophilic material.

In some embodiments, the material of the first insulating layer includes silicon oxide and/or silicon oxynitride.

In some embodiments, the display panel further includes a second insulating layer. The second insulating layer is disposed on a side of the first insulating layer away from the substrate, and a material of the second insulating layer includes at least one of silicon oxide, silicon oxynitride and silicon nitride.

In some embodiments, both the first insulating layer and the second insulating layer are of a single-layer film structure. Both the material of the first insulating layer and the material of the second insulating layer include silicon oxynitride. Alternatively, the material of the first insulating layer includes silicon oxynitride, and the material of the second insulating layer includes silicon nitride. Alternatively, the material of the first insulating layer includes silicon oxide, and the material of the second insulating layer includes silicon nitride. Alternatively, the material of the first insulating layer includes silicon oxide, and the material of the second insulating layer includes silicon oxynitride.

In some embodiments, the material of the first insulating layer includes silicon oxynitride or silicon oxide, and the material of the second insulating layer includes silicon nitride. A thickness of the first insulating layer is less than a thickness of the second insulating layer.

In some embodiments, the first encapsulation layer includes a first inorganic layer, an organic layer and a second inorganic layer that are stacked. A refractive index of the first insulating layer is smaller than a refractive index of the second inorganic layer, and a refractive index of the second insulating layer is greater than the refractive index of the first insulating layer.

In some embodiments, the first insulating layer is of a multi-layer film structure. In a direction perpendicular to the substrate and away from the substrate, multi-layer films included in the first insulating layer include a first sub-film and a second sub-film alternately stacked, and a material of the first sub-film includes silicon oxide or silicon oxynitride.

In some embodiments, the material of the first sub-film includes silicon oxide, and the material of the second sub-film includes silicon nitride. Alternatively, the material of the first sub-film includes silicon oxide, and the material of the second sub-film includes silicon oxynitride. Alternatively, the material of the first sub-film includes silicon oxynitride, and the material of the second sub-film includes silicon nitride.

In some embodiments, the second insulating layer of a multi-layer film structure. In the direction perpendicular to the substrate and away from the substrate, multi-layer films included in the second insulating layer include a third sub-film and a fourth sub-film alternately stacked; a material of the third sub-film includes silicon oxide or silicon oxynitride.

In some embodiments, a film in the multi-layer films included in the first insulating layer farthest from the substrate is the second sub-film; the material of the third sub-film includes silicon oxide, and a material of the fourth sub-film includes silicon oxynitride or silicon nitride; or the material of the second sub-film includes silicon nitride, the material of the third sub-film includes silicon oxynitride, and the material of the fourth sub-film includes silicon nitride.

In some embodiments, the first encapsulation layer includes a first inorganic layer, an organic layer and a second inorganic layer that are stacked. A refractive index of the first sub-film of the first insulating layer is smaller than a refractive index of the second inorganic layer, and a refractive index of the second sub-film of the first insulating layer is greater than the refractive index of the first sub-film of the first insulating layer. In a case where a film in the multi-layer films included in the first insulating layer farthest from the substrate is the first sub-film, the refractive index of the third sub-film is greater than the refractive index of the first sub-film, and the refractive index of the fourth sub-film is smaller than the refractive index of the third sub-film. In a case where a film in the multi-layer films included in the first insulating layer farthest from the substrate is the second sub-film, the refractive index of the third sub-film is smaller than the refractive index of the second sub-film, and the refractive index of the fourth sub-film is greater than the refractive index of the third sub-film.

In some embodiments, the display panel further includes a first metal layer, a second metal layer and a second encapsulation layer. The first metal layer is located between the first insulating layer and the second insulating layer. The second metal layer is located on a side of the second insulating layer away from the first encapsulation layer. The second encapsulation layer is located on a side of the second metal layer away from the first encapsulation layer. One of the first metal layer and the second metal layer includes a plurality of first touch electrodes, a plurality of second touch electrodes and a plurality of connection portions, and another of the first metal layer and the second metal layer includes a plurality of bridge portions. Each connection portion is connected to two adjacent first touch electrodes, and each bridge portion is connected to two adjacent second touch electrodes through via holes. Alternatively, each connection portion is connected to two adjacent second touch electrodes, and each bridge portion is connected to two adjacent first touch electrodes through via holes.

In yet another aspect, a display apparatus is provided. The display apparatus includes a driving circuit board and the display panel as described in any of the above embodiments. The driving circuit board is coupled to the display panel.

### BRIEF DESCRIPTION OF THE DRAWINGS

In order to describe technical solutions in some embodiments of the present disclosure more clearly, the accompanying drawings to be used in some embodiments of the present disclosure will be introduced briefly. Obviously, the accompanying drawings to be described below are merely some embodiments of the present disclosure, and a person of ordinary skill in the art can obtain other drawings according to those drawings. In addition, the accompanying drawings to be described below may be regarded as schematic diagrams but are not limitations on an actual size of a product, an actual process of a method and an actual timing of a signal involved in the embodiments of the present disclosure.

FIG. 1 is a structural diagram of a display motherboard, in accordance with some embodiments;

FIG. 2A is a sectional view taken along the section line A1-A1 in FIG. 1;

FIG. 2B is another sectional view taken along the section line A1-A1 in FIG. 1;

FIG. 3 is a structural diagram of a touch structure, in accordance with some embodiments;

FIG. 4 is a sectional view taken along the section line A3-A3 in FIG. 3;

FIG. 5 is a sectional view taken along the section line A2-A2 in FIG. 1;

FIG. 6 is a sectional view taken along the section line A2-A2 in FIG. 1;

FIGS. 7 to 10 are structural diagrams of a touch structure, in accordance with some embodiments;

FIG. 11 is a comparison broken-line graph of luminous efficiencies, in accordance with some embodiments;

FIGS. 12A to 12D are box plots of luminous efficiency of simulation experiments, in accordance with some embodiments;

FIG. 13 is a box plot of white light luminous efficiency according to measured data, in accordance with some embodiments;

FIGS. 14A to 14D are box plots of color shift at different angles, in accordance with some embodiments; and

FIG. 15 is a structural diagram of a display panel, in accordance with some embodiments.

### DETAILED DESCRIPTION

The technical solutions in some embodiments of the present disclosure will be described clearly and completely with reference to the accompanying drawings; however, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.”

In the description of the specification, the terms such as “one embodiment”, “some embodiments”, “exemplary embodiments”, “example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

Some embodiments may be described using the terms “coupled” and “connected” and their derivatives. For example, the term “connected” may be used in the description of some embodiments to indicate that two or more components are in direct physical or electrical contact with each other.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The use of the phrase “applicable to” or “configured to” herein means an open and inclusive expression, which does not exclude devices that are applicable to or configured to perform additional tasks or steps.

In addition, the phrase “based on” as used herein is meant to be open and inclusive, since a process, step, calculation or other action that is “based on” one or more of the stated conditions or values may, in practice, be based on additional conditions or values exceeding those stated.

The “same layer” refers to a layer structure that is formed by forming a film layer for forming specific patterns by using a same film forming process, and then performing a single patterning process by using a same mask. Depending on different specific patterns, the single patterning process may include multiple exposure, development or etching processes, and the specific patterns in the formed layer structure may be continuous or discontinuous, and these specific patterns may also be at different heights or have different thicknesses.

The term “about”, “substantially”, and “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular”, or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°, and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

Embodiments of the present disclosure provide a display motherboard 1000, referring to FIG. 1, the display motherboard 1000 is used to form display panels 100 after a cutting process. That is to say, a cutting process is performed on a single display motherboard 1000 to form a plurality of display panels 100.

With continued reference to FIG. 1, the display motherboard 1000 includes a plurality of display areas AA, peripheral areas BB each surrounding a display area AA, and a cutting area C located at least between two adjacent peripheral areas BB (i.e., located on a side of the peripheral areas BB away from the respectively display areas AA). In the manufacturing process of the display panel 100, the cutting area C of the display motherboard 1000 is cut through one or more cutting processes, so that the display motherboard 1000 is divided to form a plurality of display panels 100.

The display panel 100 includes a display area AA and a peripheral region BB surrounding the display area AA. That is to say, each display area AA and the peripheral area BB surrounding the display area AA form a display panel 100 after a cutting process. Moreover, one display area AA of the display motherboard 1000 forms a display area AA of a single display panel 100. A peripheral area BB surrounding one display area AA in the display motherboard 1000 forms a peripheral area BB of a single display panel 100. Based on this, in the embodiments of the present disclosure, the display area AA and the peripheral area BB may refer to the areas in the display motherboard 1000 or the areas in the display panel 100.

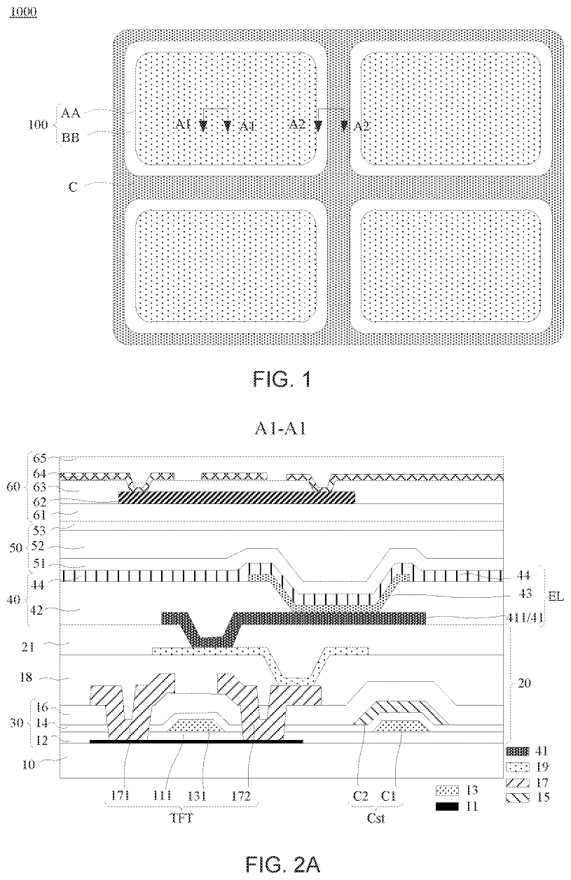

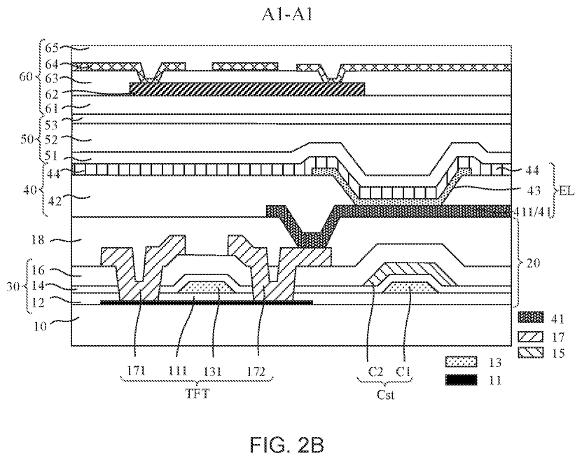

Referring to FIG. 2A, FIG. 2A is a sectional view of a display area AA of the display motherboard 1000. In the display area AA, the display motherboard 1000 may include a substrate motherboard 10, an array substrate 20 disposed on the substrate motherboard 10, a light-emitting device layer 40 and a first encapsulation layer 50 that are disposed on a side of the array substrate 20 away from the substrate motherboard 10. In a case where the display panel 100 adopts an FMLOC structure, the display motherboard 1000 further includes a touch structure 60 disposed on the first encapsulation layer 50.

In some embodiments, referring to FIG. 2A, the array substrate 20 may include a semiconductor layer 11, a first gate insulating layer 12, a first gate conductive layer 13, a second gate insulating layer 14, a second gate conductive layer 15, an interlayer dielectric layer 16, a first source-drain conductive layer 17, a first planarization layer 18, a second source-drain conductive layer 19 and a second planarization layer 21 that are stacked in sequence in a direction (from bottom to top in FIG. 2A) perpendicular to the substrate motherboard 10 and away from the substrate motherboard 10.

Alternatively, referring to FIG. 2B, the array substrate 20 may only include a semiconductor layer 11, a first gate insulating layer 12, a first gate conductive layer 13, a second gate insulating layer 14, a second gate conductive layer 15, an interlayer dielectric layer 16, a first source-drain conductive layer 17, and a first planarization layer 18 that are stacked in sequence in a direction (from bottom to top in FIG. 2B) perpendicular to the substrate motherboard 10 and away from the substrate motherboard 10.

The structure of the array substrate 20 is not specifically limited in the embodiments of the present disclosure; for example, the array substrate 20 may further include a passivation layer (not shown in the figure) between the first source-drain conductive layer 17 and the first planarization layer 18 and other film structures, which will not be listed here.

In some embodiments, the materials of the first gate insulating layer 12, the second gate insulating layer 14 and the interlayer dielectric layer 16 all include inorganic insulating materials. Based on this, the first gate insulating layer 12, the second gate insulating layer 14 and the interlayer dielectric layer 16 may also referred to as an inorganic material stacked-layer 30 as a whole.

For example, the material of the first gate insulating layer 12 include one or more of silicon nitride (SiNx, x>0), silicon oxynitride (SiON), silicon oxide (SiOx, x>0), aluminum oxide (Al₂O₃), titanium oxide (TiO₂), tantalum oxide (Ta₂O₅) and hafnium oxide (HfO₂); the first gate insulating layer 12 may be of a single-layer or multi-layer structure made of the above material. For example, the material of the first gate insulating layer 12 includes SiOx.

The material of the second gate insulating layer 14 and the material of the interlayer dielectric layer 16 may be the same as or different from the material of the first gate insulating layer 12. For example, the material of the second gate insulating layer 14 includes SiNx, and the material of the interlayer dielectric layer 16 includes SiNx and SiOx.

With continued reference to FIG. 2A, the light-emitting device layer 40 includes an anode layer 41, a pixel definition layer 42, a light-emitting functional layer 43 and a cathode layer 44 that are arranged in sequence in a direction perpendicular to the substrate motherboard 10 and away from the substrate motherboard 10. The anode layer 41 includes a plurality of anodes 411, the pixel definition layer 42 includes a plurality of openings, each opening exposes at least part of an anode 411, and at least part of the light-emitting functional layer 43 is located in an opening and is in contact with an anode 411.

In some embodiments, the material of the pixel definition layer 42 may include an organic insulating material. For example, the material of the pixel definition layer 42 may include polyimide (PI). Polyimide is a hydrophilic material.

The first encapsulation layer 50 may include a first inorganic layer 51, an organic layer 52 and a second inorganic layer 53 that are sequentially stacked. The first inorganic layer 51 and the second inorganic layer 53 may isolate moisture and oxygen, which may reduce the erosion of film structures below the first encapsulation layer 50 (proximate to a side of the substrate motherboard 10) by the external moisture and oxygen, especially reduce the risk of the erosion of the light-emitting functional layer 43 by the moisture and oxygen, so that the encapsulation performance of the display panel 100 is improved. As a result, the service life of the display panel 100 is increased. The organic layer 52 may be used to planarize the light exit surface of the display panel 100, and may be used to absorb and release the stress of the display panel 100. For example, the material of the first inorganic layer 51 and the material of the second inorganic layer 53 include an inorganic insulating material; for example, the material of the first inorganic layer 51 and the material of the second inorganic layer 53 may be silicon nitride.

In some embodiments, the display area AA includes a plurality of sub-pixels, and the sub-pixel includes a pixel circuit disposed in the array substrate 20 and a light-emitting device EL disposed in the light-emitting device layer 40. For example, the pixel circuit may include a plurality of thin film transistor (TFTs) and at least one capacitor. It will be understood that, FIG. 2A only exemplarily shows one TFT, one capacitor Cst and one light-emitting device EL.

For example, the TFT may include a semiconductor pattern 111 in the semiconductor layer 11, a gate pattern 131 in the first gate conductive layer 13, and a source 171 and a drain 172 in the first source-drain conductive layer 17. The capacitor Cst includes a first plate C1 disposed in the first gate conductive layer 13, and a second plate C2 disposed in the second gate conductive layer 15. Each light-emitting device EL includes an anode 411 located in the anode layer 41, a light-emitting functional layer 43 in contact with the anode 411, and a cathode 44.

In some embodiments, referring to FIG. 2A or 2B, the display motherboard 1000 further includes a first insulating layer 61 and a second insulating layer 63 that are disposed on the first encapsulation layer.

For example, in a case where the display motherboard 1000 further includes the touch structure 60, the display motherboard 1000 further includes a first metal layer 62, a second metal layer 64 and a second encapsulation layer 65. The first metal layer 62 is located between the first insulating layer 61 and the second insulating layer 63, the second metal layer 64 is located on a side of the second insulating layer 63 away from the first encapsulation layer 50, and the second encapsulation layer 65 is located on a side of the second metal layer 64 away from the first encapsulation layer 50. That is to say, in a direction perpendicular to the first encapsulation layer 50 (or the substrate motherboard 10) and away from the first encapsulation layer 50, the touch structure 60 includes a first insulating layer 61, a first metal layer 62, a second insulating layer 63, a second metal layer 64 and a second encapsulation layer 65 that are arranged in sequence.

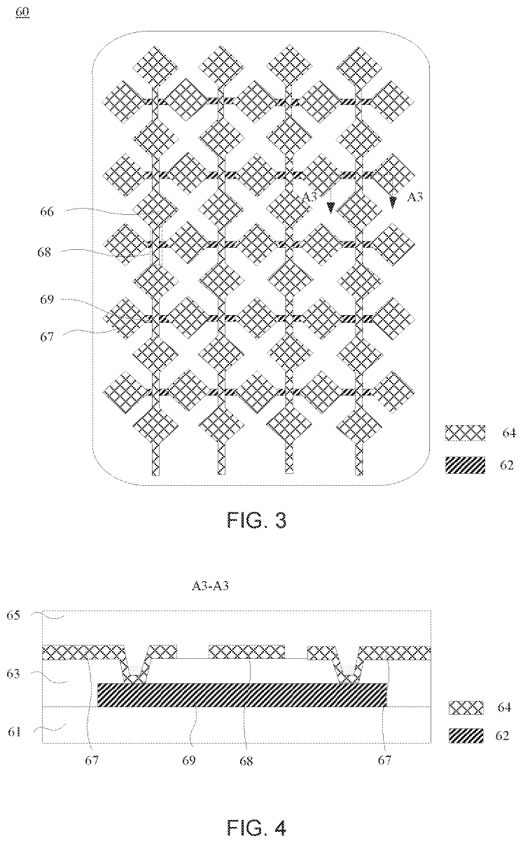

For example, one of the first metal layer 62 and the second metal layer 64 includes a plurality of first touch electrodes 66, a plurality of second touch electrodes 67 and a plurality of connection portions 68, and the other of the first metal layer 62 and the second metal layer 64 includes a plurality of bridge portions 69, referring to FIG. 3, FIG. 3 being a structural diagram of a touch structure, in accordance with some embodiments of the present disclosure. The embodiments of the present disclosure are described by taking an example in which the first metal layer 62 includes a plurality of bridge portions 69, and the second metal layer 64 includes a plurality of first touch electrodes 66, a plurality of second touch electrodes 67 and a plurality of connection portions 68 (as shown in FIG. 3).

Each connection portion 68 is connected to two adjacent first touch electrodes 66, and each bridge portion 69 is connected to two adjacent second touch electrodes 67 through via holes. Alternatively, each connection portion 68 is connected to two adjacent second touch electrodes 67, and each bridge portion 69 is connected to two adjacent first touch electrodes 66 through via holes.

For example, the embodiments of the present disclosure are described by taking an example in which each connection portion 68 is connected to two adjacent first touch electrodes 66, and each bridge portion 69 is connected to two adjacent second touch electrodes 67 through via holes (as shown in FIGS. 3 and 4). FIG. 4 is a sectional view taken along the section line A3-A3 in FIG. 3.

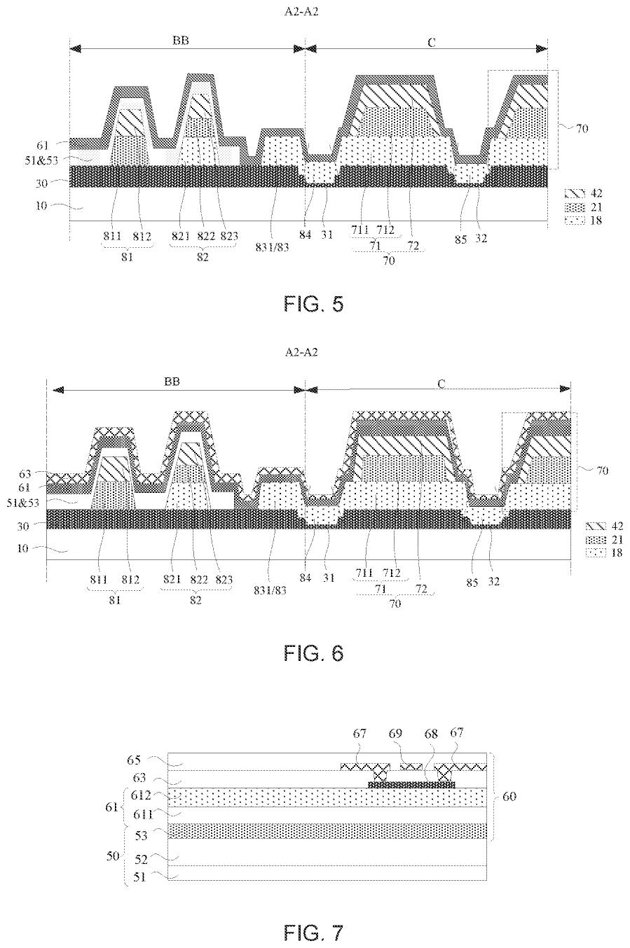

In some embodiments, referring to FIG. 5, FIG. 5 being a sectional view of a peripheral area BB and at least part of a cutting area C of the display motherboard 1000, in accordance with some embodiments, the display motherboard 1000 further includes virtual barriers 70, and the virtual barriers 70 are disposed on the substrate motherboard 10 and located in the cutting area C. The virtual barrier 70 includes a planarization layer block 71 and a pixel definition layer block 72 that are stacked, and the pixel definition layer block 72 is farther away from the substrate motherboard 10 than the planarization layer block 71.

In some embodiments, as shown in FIGS. 2A and 5, in a case where the display motherboard 1000 includes the first planarization layer 18 and the second planarization layer 21, the planarization layer block 71 includes a first sub-block 711 in the first planarization layer 18 and a second sub-block 712 in the second planarization layer 21; that is, the first sub-block 711 and the first planarization layer 18 are arranged in a same layer, and the second sub-block 712 and the second planarization layer 21 are arranged in a same layer.

An orthographic projection of the second sub-block 712 on the substrate motherboard 10 is located within an orthographic projection of the first sub-block 711 on the substrate motherboard 10, the first sub-block 711 and the second sub-block 712 forms a substantially trapezoid-shaped structure.

In some other embodiments, as shown in FIG. 2B, in a case where the display motherboard 1000 includes the first planarization layer 18 and does not include the second planarization layer 21, the planarization layer block 71 may only include a first sub-block 711 in the first planarization layer 18 (not shown in the figure); that is, the first sub-block 711 and the first planarization layer 18 are arranged in a same layer. The pixel definition layer block 72 is disposed in the pixel definition layer 42, that is, the pixel definition layer block 72 and the pixel definition layer 42 are arranged in a same layer.

With continued reference to FIG. 5, the first insulating layer 61 covers the display areas AA, the peripheral areas BB and the cutting area C, that is to say, the first insulating layer 61 covers the virtual barriers 70, and the first insulating layer 61 is in contact with the pixel definition layer blocks 72.

Referring to FIG. 6, in a case where the display motherboard 1000 further includes a second insulating layer 63, both the first insulating layer 61 and the second insulating layer 63 cover the display area AA, the peripheral area BB and the cutting area C; that is, both the first insulating layer 61 and the second insulating layer 63 cover the virtual barriers 70, the first insulating layer 61 is in contact with the pixel definition layer blocks 72, and the second insulating layer 63 is disposed on a side of the first insulating layer 61 away from the substrate motherboard 10.

In the related art, the material of the pixel definition layer may be an organic insulating material, such as PI, PI being a hydrophilic material. The material of the first insulating layer and the material of the second insulating layer are generally an inorganic insulating material, such as silicon nitride (SiN_{X}; X≥1), silicon nitride being a hydrophobic material. At the virtual barrier, the pixel definition layer block is in direct contact with the first insulating layer, one of which is a hydrophilic material, and the other is a hydrophobic material, and they have a poor adhesive force therebetween, which results in that, in the process of cutting the display motherboard to form the display panels, peeling or cracks may occur between the first insulating layer and the pixel definition layer block, and the peeling and cracks may spread to the peripheral area or even the display area, resulting in the problem of poor display of the display panel formed by the display motherboard, so that the product yield of the display panel is reduced.

In order to solve the above technical problems, in the display motherboard 1000 provided by the embodiments of the present disclosure, the material of the pixel definition layer block 72 and the material of the first insulating layer 61 each include a hydrophilic material. That is to say, in the embodiments of the present disclosure, the material of the first insulating layer 61 is replaced with a hydrophilic material. In this way, the material of the pixel definition layer block 72 and the material of the first insulating layer 61 are each a hydrophilic material, which may increase the adhesive force between the pixel definition layer block 72 and the first insulating layer 61, and reduce the risk of peeling or cracks between the pixel definition layer block 72 and the first insulating layer 61, thereby reducing the risk of poor display of the display panel 100 and improving the product yield of the display panel 100.

In some embodiments, the material of the first insulating layer 61 includes silicon oxide (SiOₓ: X≥1) and/or silicon oxynitride (SiON_{X}; X≥1). The hydrophilicity of silicon oxide and the hydrophilicity of silicon oxynitride are all greater than that of silicon nitride (the material of the first insulating layer in the related art). That is to say, in the embodiments of the present disclosure, by increasing the hydrophilicity of the material of the first insulating layer 61, the adhesive force between the first insulating layer 61 and the pixel definition layer block 72 is increased, so that the risk of poor display of the display panel 100 is reduced.

In all the embodiments of the present disclosure, silicon oxide may include silicon monoxide (SiO) and/or silicon dioxide (SiO₂). For example, silicon oxide includes silicon monoxide; or silicon oxide includes silicon dioxide; or silicon oxide includes both silicon monoxide and silicon dioxide.

For example, the material of the first insulating layer 61 may be silicon oxynitride; or the material of the first insulating layer may be silicon oxide; or the material of the first insulating layer 61 may be a mixture of silicon oxynitride and silicon oxide. Alternatively, the first insulating layer 61 may be of a multi-layer film structure, and the multi-layer film structure of the first insulating layer 61 may include a first sub-film 611 and a second sub-film 612 (with reference to the description below), and the material of the first sub-film 611 includes silicon oxide, the material of the second sub-film 612 includes silicon oxynitride. It will be understood that, in addition to silicon oxide and/or silicon oxynitride, the material of the first insulating layer 61 may also include other materials, which are not listed in the embodiments of the present disclosure.

In some embodiments, in a case where the display motherboard 1000 further includes a second insulating layer 63, the second insulating layer 63 is located on the side of the first insulating layer 61 away from the substrate motherboard 10, and the second insulating layer 63 covers the virtual barriers 70 and is in contact with the first insulating layer 61. The material of the second insulating layer 63 is at least one of silicon nitride, silicon oxynitride or silicon oxide.

For example, the material of the second insulating layer 63 may include silicon nitride. In this way, the change to the material of the display motherboard 1000 may be reduced to reduce the influence on other properties (such as film thickness, processing difficulty and structural strength) of the display motherboard 1000. It will be understood that in the embodiments of the present disclosure, unless otherwise specified, “other properties of the display motherboard 1000” may refer to at least one property other than the adhesive force between the first insulating layer 61 and the pixel definition layer block, such as the thickness of the second insulating layer 63, the processing technology of the second insulating layer 63, the sensitivity of the touch structure 60, the luminous efficiency of the display panel 100, and the chromaticity coordinate of the display panel 100, which are not listed one by one in the embodiments of the present disclosure.

For example, the material of the second insulating layer 63 includes silicon oxynitride. In this way, while improving the hydrophilicity of the first insulating layer 61, the hydrophilicity of the second insulating layer 63 may also be improved, so that the adhesive force between the first insulating layer 61 and the second insulating layers 63 is increased to reduce the risk of peeling between the first insulating layer 61 and the second insulating layer 63.

For example, the material of the second insulating layer 63 includes silicon oxynitride. In this way, the hydrophilicity of the second insulating layer 63 may be further improved, so that the adhesive force between the first insulating layer 61 and the second insulating layers 63 is increased to reduce the risk of peeling between the first insulating layer 61 and the second insulating layer 63. It will be noted that the hydrophilicity of silicon oxide is greater than that of silicon oxynitride, and the hydrophilicity of silicon oxynitride is greater than that of silicon nitride.

In some embodiments, both the first insulating layer 61 and the second insulating layer 63 are of a single-layer film structure. That is, the first insulating layer 61 and the second insulating layer 63 are both formed by a single film forming process. The material combination of the first insulating layer 61 and the second insulating layer 63 may various, such as following Examples.

In Example 1, both the material of the first insulating layer 61 and the material of the second insulating layer 63 include silicon nitride. The first insulating layer 61 and the second insulating layer 63 are made of the same material, which may increase the material identity of the display motherboard 1000 and reduce the manufacturing cost of the display motherboard 1000. Thus, it is possible to minimize the risk of film separation between the first insulating layer 61 and the second insulating layer 63.

In Example 2, the material of the first insulating layer 61 includes silicon oxynitride, and the material of the second insulating layer 63 includes silicon nitride. In this way, the adhesive force between the first insulating layer 61 and the pixel definition layer block 72 may be increased, and the adjustment and change to the display motherboard 1000 may be reduced, thereby reducing the influence on other performances of the display motherboard 1000.

In Example 3, the material of the first insulating layer 61 includes silicon oxide, and the material of the second insulating layer 63 includes silicon nitride; studies have shown that the hydrophilicity of silicon oxide is greater than that of silicon nitride, based on this, it may be possible to further improve the adhesive force between the first insulating layer 61 and the pixel definition layer block 72, reduce the risk of peeling between the first insulating layer 61 and the pixel definition layer block 72, and reduce the influence on other properties of the display motherboard 1000.

In Example 4, the material of the first insulating layer 61 includes silicon oxide, and the material of the second insulating layer 63 includes silicon oxynitride. It is possible to increase the adhesive force between the first insulating layer 61 and the second insulating layer 63, and reduce the risk of peeling between the first insulating layer 61 and the second insulating layer 63.

In Example 5, both the material of the first insulating layer 61 and the material of the second insulating layer 63 include silicon oxide. In this way, not only the adhesive force between the first insulating layer 61 and the pixel definition layer block 72 may be increased, but also the risk of layer separation between the first insulating layer 61 and the pixel definition layer block 72 may be reduced. Moreover, it may be possible to increase the adhesive force between the first insulating layer 61 and the second insulating layer 63, and reduce the risk of peeling between the first insulating layer 61 and the second insulating layer 63.

In some embodiments, referring to FIG. 6, the pixel definition layer block 72 covers a surface of the second sub-block 712 away from the substrate motherboard 10 and sidewalls of the second sub-block 712; the sidewalls of the second sub-block 712 refer to a sidewall of the second sub-block 712 proximate to the peripheral area BB and a sidewall of the second sub-block 712 away from the peripheral area BB. That is to say, the pixel definition layer block 72 and the first sub-block 711 together encase the surfaces of the second sub-block 712. In this way, it may be possible to increase the contact area between the pixel definition layer block 72 and the first insulating layer 61, and reduce the contact area between the second sub-block 712 and the first insulating layer 61, which increases the adhesive force between the pixel definition layer block 72 and the first insulating layer 61, so that the risk of peeling between the pixel definition layer block 72 and the first insulating layer 61 during the manufacturing process of the display motherboard 1000 (during the process of cutting to form the display panel 100) is reduced, and the risk of cracks of the display motherboard 1000.

With reference to Table 1 below:

TABLE 1
Film-forming properties of silicon nitride and silicon oxynitride

| | | Basic | | | |
|---|---|---|---|---|---|
| Item | | requirement | SiNx | SiONx | Remark |
| Deposition rate | | >2100 | 2100-2800 | 3000-3300 | Feasible |
| Film thickness | | ≤5% | ≤3 | 3.3-4.6 | Feasible |
| uniformity (%) | | | | | |
| Refractive index | | | 1.80-1.91 | 1.566-1.78 | — |
| Stress (Mpa) | | | 310 | 0-100 | — |
| PECVD | Cleaning | | 13700 | −11000 | Decrease |
| | rate | | | | 19.7% |
| | (λ/min) | | | | |
| Etching | Etching | 3000 ± 6% | 2975 | 2211 | Decrease |
| process | speed | | | | 25.7% |
| | (λ/min) | | | | |
| | Etching | — | 13 | 17 | Feasible |
| | uniformity | | | | |
| | (%) | | | | |
| | Tilt angle | Avg 85 | 73-91 | 72-88 | Feasible |

The film-forming properties of silicon nitride and silicon oxynitride are exemplarily compared in Table 1. “Feasible” means that the process feasibility meets the film-forming requirements. From Table 1, it can be seen that silicon nitride and silicon oxynitride have a small difference in the deposition rate, film thickness uniformity, refractive index and stress, so that the influence on the display motherboard 1000 is small and negligible. That is to say, in a case where the first insulating layer 61 (or the second insulating layer 63) is made of silicon nitride or silicon oxynitride, the influence of deposition rate, film thickness uniformity, refractive index and stress on the display motherboard 1000 is small.

However, there is a certain difference, after film formation (after the corresponding insulating layer is formed), between silicon oxynitride and silicon nitride in terms of the cleaning rate, the etching rate of dry etching, and the uniformity of etching. For example, the cleaning rate and dry etching rate of silicon oxynitride are both decrease compared to silicon nitride to varying degrees, which will affect part of the production capacity. Moreover, it can be found through research that the above-mentioned effects have no effect on the process feasibility of silicon oxynitride (at least one of the first insulating layer 61 and the second insulating layer 63 is made of silicon oxynitride); that is, under the same process condition, it is possible to use silicon oxynitride to manufacture the first insulating layer 61 and/or the second insulating layer 63.

In some implementations, in order to reduce the effect of the silicon oxynitride material on the processing efficiency of the display motherboard 1000, as shown in Example 2, in a case where the material of the first insulating layer 61 includes silicon oxynitride and the material of the second insulating layer 63 includes silicon nitride, the thickness of the first insulating layer 61 is smaller than the thickness of the second insulating layer 63 (in a case where both the first insulating layer 61 and the second insulating layer 63 are made of silicon nitride, they have the same thickness). That is to say, by reducing the thickness of the first insulating layer 61 (a silicon oxynitride material layer), it is possible to reduce or even eliminate the effect on the manufacturing efficiency of the display motherboard 1000 caused by the change of the material of the first insulating layer 61. Moreover, by reducing the thickness of the first insulating layer 61, it may be possible to reduce the defects (e.g., differences in uniformity and compactness at different positions) in the first insulating layer 61, and increase the tensile strength and elongation of the first insulating layer 61, thereby increasing the tensile strength and elongation of the display motherboard 1000.

Based on the above embodiments, it will be understood that in a case where at least one of the first insulating layer 61 and the second insulating layer 63 is made of silicon oxynitride material, the thickness of the corresponding film layer may be reduced, and the effect on the manufacturing process of the display motherboard 1000 due to material changes may be reduced, so as to increase the tensile strength and elongation of the display motherboard 1000.

For example, in the related art, in the case where the first insulating layer 61 or the second insulating layer 63 is made of silicon nitride material, the thickness of which may be in a range of 0.2 μm to 0.5 μm. For example, in the case where the first insulating layer 61 is made of silicon nitride material, the thickness of the first insulating layer 61 may be 0.2 μm, 0.35 μm or 0.5 μm, or the like, which are not listed in the embodiments of the present disclosure.

In the embodiments of the present disclosure, in the case where the first insulating layer 61 or the second insulating layer 63 is made of the silicon oxynitride material, the thickness of which may be reduced by 15% to 35% compared with that of which made of the silicon nitride material. For example, in the case where the first insulating layer 61 or the second insulating layer 63 is made of the silicon oxynitride material, the thickness of which may be in a range of 0.15 μm to 0.4 μm. For example, in the case where the first insulating layer 61 is made of the silicon oxynitride material, the thickness of the first insulating layer 61 may be 0.15 μm, 0.3 μm, 0.4 μm, or the like, which will not be listed in the embodiments of the present disclosure.

In some embodiments, referring to FIG. 2A, in the display area AA, in the case where the first encapsulation layer 50 includes the first inorganic layer 51, the organic layer 52 and the second inorganic layer 53 that are stacked, the refractive index of the first insulating layer 61 is smaller than the refractive index of the second inorganic layer 53, and the refractive index of the second insulating layer 63 is greater than the refractive index of the first insulating layer 61; that is, the second inorganic layer 53, the first insulating layer 61, and the second insulating layer 63 are a high-refractive-index layer, a low-refractive-index layer, and a high-refractive-index layer in order.

Due to the effect of micro-cavity, in a case where the high-refractive-index material and the low-refractive-index material are cross used, for the light emitted by the sub-pixel, the light transmission may be improved through the micro-cavity effect due to the difference in refractive index between the materials; that is, the luminous efficiency of the display motherboard is improved due to the micro-cavity effect. The specific principle is that when two light waves with different wavelengths superimpose to be at a same phase, constructive interference occurs, thereby increasing the light transmittance of the second inorganic layer 53, the first insulating layer 61 and the second insulating layer 63. The condition for the occurrence of constructive interference is: 2nd=mλ, where d refers to a distance of the micro-cavity (the thickness of the second inorganic layer 53, the first insulating layer 61 or the second insulating layer 63), n refers to the refractive index of the material of the micro-cavity, m refers to the number of superimposing, and λ refers to the wavelength of the incident light. In a case where adjacent film layers are made of materials with different refractive index, the effect of the micro-cavity is strengthened, so that the luminous efficiency of the display motherboard 1000 in the display area AA is improved.

For example, the refractive index of silicon nitride is greater than the refractive index of silicon oxynitride, and the higher the oxygen content in the silicon oxynitride material, the lower the refractive index. The refractive index of silicon oxynitride is greater than the refractive index of silicon oxide. For example, the refractive index of silicon dioxide is approximately in a range of 1.8 to 2.00, the refractive index of silicon oxynitride is approximately in a range of 1.50 to 1.70, and the refractive index of the silicon oxide is approximately in a range of 1.35 to 1.55.

In some embodiments, the first insulating layer 61 is of a multi-layer film structure; that is to say, the first insulating layer 61 may be the sum of multiple film layers. In the direction perpendicular to the substrate motherboard 10 and away from the substrate motherboard 10, the multi-layer films included in the first insulating layer 61 include first sub-film(s) 611 and second sub-film(s) 612 alternately stacked; for example, as shown in FIGS. 7, 8 and 10, a film layer in the first insulating layer 61 closest to the substrate motherboard 10 is the first sub-film 611. The material of the first sub-film 611 includes silicon oxide or silicon oxynitride. In this way, it is possible to increase the adhesion force between the first sub-film 611 and the pixel definition layer pad 72, which increases the adhesion force between the first insulating layer 61 and the pixel definition layer block 72, so that the risk of poor display of the display motherboard 1000 in the display area AA is reduced.

The number of the first sub-films 611 and the number of the second sub-films 612 included in the first insulating layer 61 are not specifically limited in the embodiments of the present application. For example, the number of the first sub-films 611 and the number of the second sub-films 612 may be the same or different, and the number of the first sub-films 611 and the number of the second sub-films 612 may be one or more. For example, the first insulating layer 61 may include one first sub-film 611 and one second sub-film 612 (as shown in FIG. 7), or include two first sub-films 611 and two second sub-films 612, or includes two first sub-films 611 and one second sub-film 612, which is not listed one by one in the embodiments of the present disclosure.

For example, in the case where the first insulating layer 61 includes the first sub-film(s) 611 and the second sub-film(s) 612, the total thickness of the first insulating layer 61 may be in a range of 0.2 μm to 0.5 μm. That is to say, by reducing the thickness of each of the first sub-film 611 and the second sub-film 612, it may be possible to ensure that the total thickness of the first insulating layer 61 is approximately equal to the thickness of the first insulating layer 61 in the case of which is of a single-layer film structure. In this way, the thickness of the display motherboard 1000 may be reduced, which is beneficial to lightness and thinness of the display apparatus.

In some embodiments, the material of the first sub-film 611 includes silicon oxide, and the material of the second sub-film 612 includes silicon nitride. Alternatively, the material of the first sub-film 611 includes silicon oxynitride, and the material of the second sub-film 612 includes silicon nitride. Alternatively, the material of the first sub-film 611 includes silicon oxide, and the material of the second sub-film 612 includes silicon oxynitride. In this way, it may be possible to satisfy that the refractive index of the second sub-film 612 may be greater than that of the first sub-film 611, which facilitates the formation of the micro-cavity by the first insulating layer 61 to improve the luminous efficiency of the display motherboard 1000 in the display area AA.

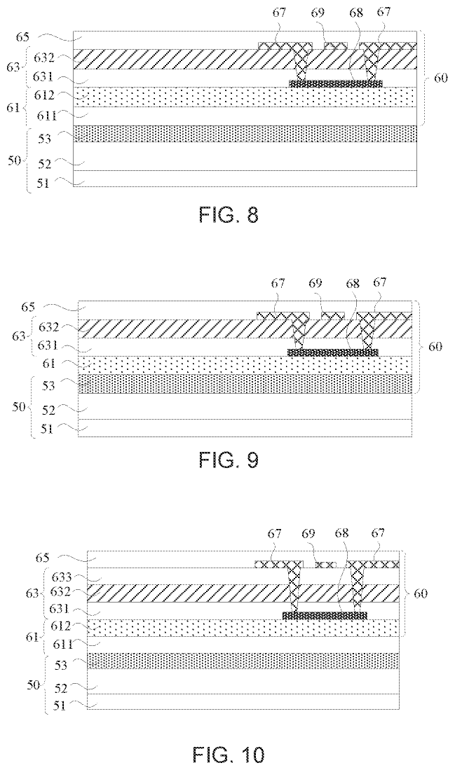

In some embodiments, as shown in FIG. 8, the second insulating layer 63 may also be of a multi-layer film structure. In the direction perpendicular to the substrate motherboard 10 and away from the substrate motherboard 10, the multi-layer films included in the second insulating layer 63 include third sub-films 631 and fourth sub-films 632 that are alternately stacked. A film in the multi-layer films included in the second insulating layer 63 closest to the substrate motherboard 10 is the third sub-film 631. The material of the third sub-film 631 includes silicon oxide or silicon oxynitride. In this way, the hydrophilicity of the third sub-film 631 is relatively high, which may increase the adhesive force between the third sub-film 631 and the first insulating layer 61, so that the risk of peeling between the second insulating layer 63 and the first insulating layer 61 is reduced.

In some embodiments, a film in the multi-layer films included in the first insulating layer 61 farthest from the substrate motherboard 10 is the second sub-film 612 (as shown in FIGS. 7, 8 and 10). The material of the third sub-film 631 includes silicon oxide, and the material of the fourth sub-film 632 includes silicon oxynitride or silicon nitride. Alternatively, in a case where the material of the second sub-film 612 includes silicon nitride, the material of the third sub-film 631 includes silicon oxynitride, and the material of the fourth sub-film 632 includes silicon nitride.

That is to say, in a case where the material of the third sub-film 631 includes silicon oxide, and the material of the fourth sub-film 632 includes silicon oxynitride or silicon nitride, the material of the first insulating layer 61 may be selected from the material in any of the foregoing embodiments. Moreover, in a case where the material of the second sub-film 612 of the first insulating layer 61 includes silicon nitride, the material of the third sub-film 631 includes silicon oxynitride, and the material of the fourth sub-film 632 includes silicon nitride.

The number of the third sub-films 631 and the number of the fourth sub-films 632 included in the second insulating layer 63 are not specifically limited in the present application. For example, the number of the third sub-films 631 and the number of the fourth sub-films 632 may be the same or different, and the number of the third sub-films 631 and the number of the fourth sub-films 632 may be one or more. For example, the second insulating layer 63 may include one third sub-film 631 and one fourth sub-film 632 (as shown in FIG. 8), or include two third sub-films 631 and two fourth sub-films 632, or includes two third sub-films 631 and one fourth sub-film 632, which is not listed one by one in the embodiments of the present disclosure.

For example, in the case where the second insulating layer 63 includes the third sub-film(s) 631 and the fourth sub-film(s) 632, the total thickness of the second insulating layer 63 may be in a range of 0.2 μm to 0.5 μm. That is, by reducing the thickness of each of the third sub-film 631 and the fourth sub-film 632, it may be possible to ensure that the total thickness of the second insulating layer 63 is approximately equal to the thickness of the second insulating layer 63 in the case of which is of a single-layer film structure. In this way, the thickness of the display motherboard 1000 may be reduced, which is beneficial to lightness and thinness of the display apparatus.

In the present application, the above multiple embodiments may be varied or combined, especially, in the case where the first insulating layer 61 and the second insulating layer 63 are both of a multi-layer film structure, there are multiple combinations for the number of film layers of the first insulating layer 61 and the material selection of each film layer, and the number of the second insulating layer 63 and the material selection of each film layer, such as following Examples.

In Example 6, the first insulating layer 61 includes one first sub-film 611 and one second sub-film 612, the material of the first sub-film 611 includes silicon oxynitride, and the material of the second sub-film 612 includes silicon nitride. The second insulating layer 63 includes one third sub-film 631 and one fourth sub-film 632, the material of the third sub-film 631 includes silicon oxide, and the material of the fourth sub-film 632 includes silicon nitride.

In Example 7, the first insulating layer 61 includes one first sub-film 611 and one second sub-film 612, the material of the first sub-film 611 includes silicon oxide, and the material of the second sub-film 612 includes silicon nitride. The second insulating layer 63 includes one third sub-film 631 and one fourth sub-film 632, the material of the third sub-film 631 includes silicon oxide, and the material of the fourth sub-film 632 includes silicon nitride.

In Example 8, the first insulating layer 61 includes one first sub-film 611 and one second sub-film 612, the material of the first sub-film 611 includes silicon oxide, and the material of the second sub-film 612 includes silicon oxynitride. The second insulating layer 63 includes one third sub-film 631 and one fourth sub-film 632, the material of the third sub-film 631 includes silicon oxide, and the material of the fourth sub-film 632 includes silicon oxynitride.

In Example 9, the first insulating layer 61 includes one first sub-film 611 and one second sub-film 612, and the material of the first sub-film 611 includes silicon oxynitride, and the material of the second sub-film 612 includes silicon nitride. The second insulating layer 63 includes one third sub-film 631 and one fourth sub-film 632, the material of the third sub-film 631 includes silicon oxide, and the material of the fourth sub-film 632 includes silicon nitride.

The combinations of the above multiple embodiments are not listed one by one in the embodiments of the present disclosure, it will be understood that different combinations and simple replacements for the above multiple embodiments are all included in the protection scope of the present application.

In some embodiments, the first encapsulation layer 50 includes a first inorganic layer 51, an organic layer 52 and a second inorganic layer 53 that are stacked. The refractive index of the first sub-film 611 of the first insulating layer 61 is smaller than the refractive index of the second inorganic layer 53, and the refractive index of the second sub-film 612 of the first insulating layer 61 is greater than the refractive index of the first sub-film 611 of the first insulating layer 61. In this way, the second inorganic layer 53 and the multi-layer film structure of the first insulating layer 61 may constitute a structure in which high-refractive index material layers and low-refractive index material layers stacked alternatively, which is conducive to improving the luminous efficiency of the display motherboard 1000 in the display area AA.

In a case where a layer of the multi-layer films included in the first insulating layer 61 farthest from the substrate motherboard 10 is the first sub-film 611, the refractive index of the third sub-film 631 is greater than the refractive index of the first sub-film 611, and the refractive index of the fourth sub-film 632 is smaller than the refractive index of the third sub-film 631. In this way, the second inorganic layer 53, the multi-layer film structure of the first insulating layer 61 and the multi-layer film structure of the second insulating layer 63 may constitute a structure in which high-refractive index material layers and low-refractive index material layers stacked alternatively, which is conducive to improving the luminous efficiency of the display motherboard 1000 in the display area AA.

In a case where a film of the multi-layer films included in the first insulating layer 61 farthest from the substrate motherboard 10 is the second sub-film 612, the refractive index of the third sub-film 631 is smaller than the refractive index of the second sub-film 612, and the refractive index of the fourth sub-film 632 is greater than the refractive index of the third sub-film 631. In this way, the second inorganic layer 53, the multi-layer film structure of the first insulating layer 61 and the multi-layer film structure of the second insulating layer 63 may constitute a structure in which high-refractive index material layers and low-refractive index material layers stacked alternatively, which is conducive to improving the luminous efficiency of the display motherboard 1000 in the display area AA.

In some embodiments, one of the first insulating layer 61 and the second insulating layer 63 may be of a single-layer film structure, and the other may be of a multi-layer film structure.

In Example 10, as shown in FIG. 9, the first insulating layer 61 may be of a single-layer film structure, and the material of the first insulating layer 61 may be silicon oxynitride. The second insulating layer 63 includes one third sub-film 631 and one fourth sub-film 632. The material of the third sub-film 631 includes silicon oxynitride, and the material of the fourth sub-film 632 includes silicon nitride.

In Example 11, as shown in FIG. 7, the first insulating layer 61 includes one first sub-film 611 and one second sub-film 612, the material of the first sub-film 611 includes silicon oxynitride, and the material of the second sub-film 612 includes silicon nitride. The second insulating layer 63 is of a single-layer film structure, and the material of the first insulating layer 61 may be silicon oxynitride or silicon oxide.

Examples for “one of the first insulating layer 61 and the second insulating layer 63 is of a single-layer film structure, and the other is of a multi-layer film structure” will not be listed one by one in the embodiments of the present disclosure.

In some embodiments, in the case where the first insulating layer 61 (or the second insulating layer 63) is of a multi-layer film structure, the multi-layer films included in the first insulating layer 61 (or the second insulating layer 63) may also include three film layers with different materials.

In Example 12, as shown in FIG. 10, the first insulating layer 61 includes one first sub-film 611 and one second sub-film 612, and the material of the first sub-film 611 includes silicon oxide, and the material of the second sub-film 612 includes silicon oxynitride. The second insulating layer 63 includes one third sub-film 631, one fourth sub-film 632 and one fifth sub-film 633. The material of the third sub-film 631 includes silicon oxide, the material of the fourth sub-film 632 includes silicon oxynitride, and the material of the fifth sub-film 633 includes silicon nitride. In this way, the hydrophilicity of the multi-layer films included in the second insulating layer 63 gradually increases, which may increase the adhesive force between two adjacent film layers and reduce the risk of peeling between film layers.

In some embodiments, referring to FIG. 6, the display motherboard 1000 further includes a first barrier 81, a second barrier 82 and an anti-crack barrier 83. The first barrier 81, the second barrier 82 and the anti-crack barrier 83 are located in the peripheral area BB and surround the display area AA, and are arranged at intervals in a direction away from the display area AA.

The first barrier 81 includes a third sub-block 811 disposed in the second planarization layer 21, and a fourth sub-block 812 disposed in the pixel definition layer 42. An orthographic projection, on the substrate motherboard 10, of the fourth sub-block 812 is located within an orthographic projection, on the substrate motherboard 10, of the third sub-block 811.

The second barrier 82 includes a fifth sub-block 821 disposed in the first planarization layer 18, a sixth sub-block 822 disposed in the second planarization layer 21, and a seventh sub-block 823 disposed in the pixel definition layer 42. On the substrate motherboard 10, an orthographic projection of the seventh sub-block 823 is located within an orthographic projection of the sixth sub-block 822, and the orthographic projection of the sixth sub-block 822 is located within an orthographic projection of the fifth sub-block 821.

The anti-crack barrier 83 is located in the peripheral area BB and on a side of the second barrier 82 away from the first barrier, and the anti-crack barrier 83 includes an eighth sub-block 831 disposed in the first planarization layer 18.

With continued reference to FIG. 6, in some embodiments, the inorganic material stacked-layer 30 further includes a first groove 31 located between the virtual barrier 70 and the peripheral area BB, and a second groove 32 located between two adjacent virtual barriers 70. The display motherboard 1000 further includes a first connecting portion 84 and a second connecting portion 85.

The first connecting portion 84 is at least partially located in the first groove 31 and connected to the eighth sub-block 831 and the first sub-block 711. The second connecting portion 85 is at least partially located in the second groove 32 and connected to the first sub-blocks 711 of two adjacent virtual barriers 70.

In the embodiments of the present disclosure, relevant experiments have carried out to verify the effect of reducing the peeling in the production process in some of the above Examples. With reference to Table 2 below:

TABLE 2
Probability of peeling and cracks generation
in Example 1, Example 2 and Example 6

| | Defective rate of peeling in different regions | | | | | | |
|---|---|---|---|---|---|---|---|
| | | | | | Edge of | | |
| | AA | | | Bonding | peripheral | | Module |
| Item | opening | AA | TEG | region | area | Yield | cracks |
| Control | 0.10% | 0% | 100% | 18.50% | 33% | 96.32% | 65.50% |
| Example 1 | 0% | 0% | 0% | 0% | 0% | 97.63% | 13.30% |
| Example 2 | 0% | 0% | 0% | 0% | 0% | 99.47% | 6.70% |
| Example 6 | 0% | 0% | 0% | 0% | 0% | 100% | 0% |

In Table 2, the “Control” group is the solution adopted by the related art, that is, both the first insulating layer 61 and the second insulating layer 63 are of a single-layer film structure, and both the material of the first insulating layer 61 and the material of the second insulating layer 63 are silicon nitride.

In Example 1, Example 2 and Example 6, the structures and film materials of the first insulating layer 61 and the second insulating layer 63 respectively correspond to the corresponding examples above.

In Example 1 and Example 2, the first insulating layer 61 and the second insulating layer 63 are both of a single-layer film structure, and the thickness of the first insulating layer 61 and the thickness of the second insulating layer 63 are respectively equal to the thickness of the first insulating layer 61 and the thickness of the second insulating layer 63 that are in the “Control” group. Moreover, other variables are controlled to be respectively the same; for example, the structures of the array substrate 20, the light-emitting device layer 40 and the first encapsulation layer 50 are respectively the same.

In Example 6, both the first insulating layer 61 and the second insulating layer 63 include two films, and the total thickness of the first insulating layer 61 and the total thickness of the second insulating layer 63 are respectively equal to the thickness of the first insulating layer 61 and the thickness of the second insulating layer 63 in the “Control” group, and other variables are controlled to be respectively the same.

It can be seen from Table 2 that after changing the material of the first insulating layer 61, the peeling phenomenon in the test element group (TEG) region (a region for providing the test elements in the peripheral area) can be significantly ameliorated. Furthermore, the peeling phenomenon in the bonding region in the peripheral area and the edge of the peripheral area of the display panel is significantly ameliorated, and the product yield of the display panel 100 is improved.

“Module cracks” refers to cracks occurring at the edge of the display panel 100 during the module process. In the above three Examples, the risk of cracks in the display panel 100 is significantly reduced compared to the “Control” group, which is beneficial to improving the product yield of the display panel 100.

In Table 2, the highest product defect rate is 13.3% (Example 1), and the lowest product defect rate is 0 (Example 6). Therefore, the embodiments of the present application may improve the product yield of the display panel 100 compared to the related art (“Control”).

In the embodiments of the present application, simulation experiments for the luminous efficiency and RGB chromaticity coordinates of the display panel 100 in some of the above Examples are carried out by the inventors to verify and evaluate the degree of improvement of the luminous efficiency of the improvement scheme in advance, and simulation experiments for the optically related RGB chromaticity coordinates and viewing angle color shift are carried out. With reference to Table 3 and Table 4 below.

TABLE 3
Simulation experiments for the luminous efficiency
of the display panel in different Examples

| | Efficiency(%) | | | | | | |
|---|---|---|---|---|---|---|---|
| | White | Red | Green | Blue | Chromaticity coordinates | | |
| Item | light | light | light | light | Rx | Gx | By |
| Control | 100 | 100 | 100 | 100 | 0.681 | 0.2503 | 0.0051 |
| Example 1 | 103.3 | 101.5 | 101.7 | 104.8 | 0.6809 | 0.2485 | 0.0553 |
| Example 2 | 100.9 | 100.9 | 95.2 | 102.9 | 0.6809 | 0.2474 | 0.0552 |
| Example 6 | 100.7 | 100.3 | 98.7 | 101.4 | 0.6808 | 0.2499 | 0.0549 |

TABLE 4
Simulation experiments for the white luminous efficiency
of the display panel in different Examples

| White light | Maximum value | Average value | Minimum value |
|---|---|---|---|
| Control | 120 | 86 | 50 |
| Example 1 | 124 | 88.8 | 51.7 |
| Example 2 | 121.2 | 86.86 | 50.5 |
| Example 6 | 120.8 | 86.6 | 50.4 |

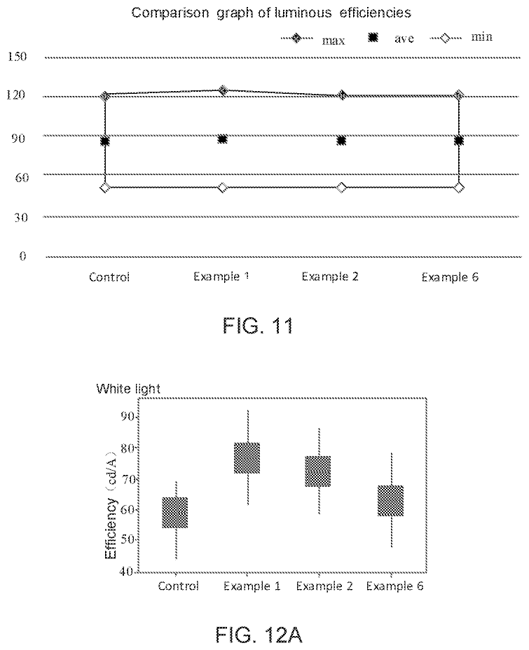

In Table 3, the efficiency value is converted into percentage data, and the luminous efficiency of each color in the “Control” group is 100% for comparison. Referring to FIG. 11 and Table 4, FIG. 11 is a comparison graph of the luminous efficiency of white light in the related simulation experiments.

It can be seen from Table 3, Table 4 and FIG. 11 that the simulation results are consistent with the theoretical results. Compared to the related art (Control), the luminous efficiency of white light in Example 1, Example 2 and Example 6 are all improved. Example 1 has the highest improvement rate, and the luminous efficiency of white light has increased by 3.3% compared to the related art (Control). There is a difference in the effect on the micro-cavity in different light-emitting wavebands after the refractive index of the first insulating layer 61 and the refractive index of the second insulating layer 63 are changed, so the effect on RGB monochromatic efficiency is different in different Examples. For example, the luminous efficiency of green light in Example 2 even falls compared to the related art (Control), but the monochromatic luminous efficiency of blue light, which has the greatest effect on the luminous efficiency of white light, is increased to varying degrees, and Example 1 has the largest increase, increasing by 4.8%. The change of the material of the first insulating layer 61 and the material of the second insulating layer 63 has little effect on the chromaticity coordinates of the monochromatic color, the change of CIE is not obvious, and it has almost no effect on the color shift track under the viewing angle.

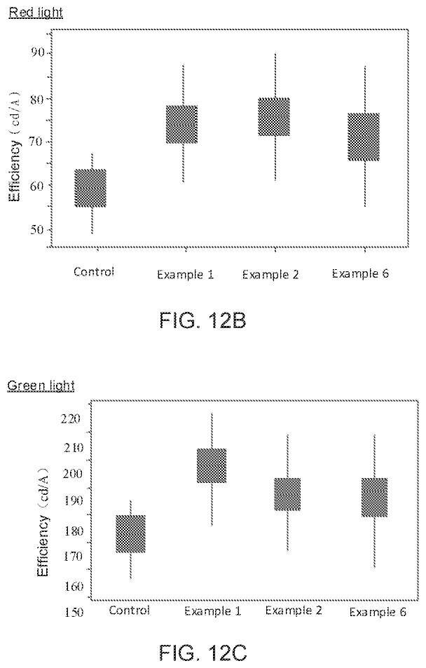

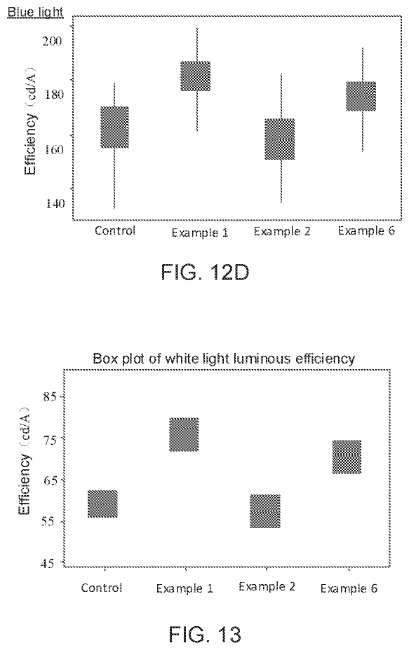

Based on the results of theory and simulation experiments, referring to FIGS. 12A to 12D, the luminous efficiency of actual products of the display panel 100 in some of the above embodiments is verified by the inventors of the present application, so as to evaluate the effect of the change of the materials of the first insulating layer 61 and the second insulating layer 61 on the optical properties of the display panel 100. FIGS. 12A to 12D are box plots of luminous efficiency of different colors for the products corresponding to Example 1, Example 2, and Example 6, respectively.

The results obtained from these figures are substantially the same as the results obtained in Table 3, Table 4, and FIG. 11. As shown in FIGS. 12A to 12D, the luminous efficiencies of white light in Example 1, Example 2, and Example 6 are all improved compared to the related art (Control). There is a difference in the effect on the micro-cavity in different light-emitting wavebands after the refractive index of the first insulating layer 61 and the refractive index of the second insulating layer 63 are changed, so the effect on RGB monochromatic efficiency is different in different Examples. For example, as shown in FIGS. 12B and 12C, it can be found from the comparison of the luminous efficiencies of red light and green light that the luminous efficiencies of red light and green light are all improved in Example 1, Example 2 and Example 6 compared to the related art (Control). However, as shown in FIG. 12D, it can be found from the comparison of the luminous efficiencies of blue light that the luminous efficiencies of blue light in Example 1 and Example 6 are improved compared to the related art (Control), but the luminous efficiency of blue light in Example 2 is reduced compared to the related art (Control).

In summary, for Example 1, Example 2 and Example 6, the luminous efficiency of white light of the display panel is improved. That is to say, in the embodiments of the present disclosure, after changing the materials of the first insulating layer 61 and the second insulating layer 63, the luminous efficiency of the display panel 100 is improved, so that the luminous efficiency of the display panel 100 may be improved.

In addition, after a module process is performed on the display panel 100 to form a display apparatus, for example, a support structure (a foam buffer layer, a grid adhesive layer, a rigid support layer, etc.) is provided on the backlight side of the display panel 100, and a polarizer and a cover plate are provided on the light exist side of the display panel 100, the luminous efficiency of the display panel after the module process is verified through product testing.

Referring to FIG. 13, similar to the theoretical and simulation results of the display panel 100 substantially, the luminous efficiency of white light in Example 1 and Example 6 is improved compared to the related art (Control). The luminous efficiency of white light In Example 2 is not significantly improved or decreased compared to the related art, i.e., the luminous efficiency of the display panel is at least not be reduced.

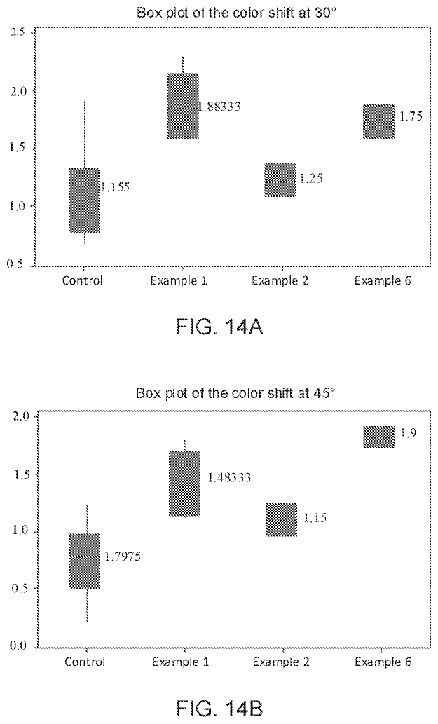

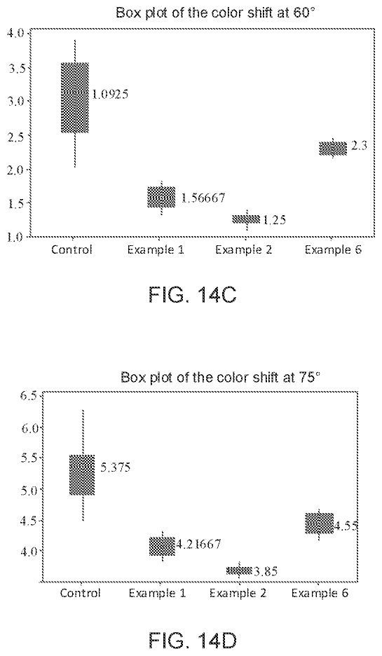

In addition, the color shift of the display module at different angles in some of the above embodiments is also verified through product testing by the inventors. Referring to FIGS. 14A to 14D, it can be seen from the comparison of the color shift under different viewing angles that the change of the materials of the first insulating layer 61 and the second insulating layer 63 has little influence on the viewing angle color shift track of the display panel. Moreover, in terms of value of the viewing angle color shift, the just noticeable color difference (JNCD) at a small viewing angle increases slightly, while the JNCD at a large viewing angle decreases significantly. It can be seen that, in Example 1, Example 2, and Example 6, there is no obvious negative effect on the color shift of the display panels, but the yellowing at large viewing angles may be reduced to a certain extent. The ordinates in FIGS. 14A to 14D are all JNCD; FIG. 14A shows the color shift at a viewing angle of 30°, FIG. 14B shows the color shift at a viewing angle of 45°, FIG. 14C shows the color shift at a viewing angle of 60°, and FIG. 14D shows the color shift at a viewing angle of 75°.

In a case where the display panel 100 further includes a touch structure 60, i.e., the first insulating layer 61 and the second insulating layer 63 are insulating layers inside of the touch structure 60, referring to Table 5 below, the touch performance of the display panel 100 is simulation tested and verified based on the theoretical value of the dielectric constant by the inventors.

TABLE 5
Comparison table of touch performance
of display panels in different Examples

| Type | | | Exam- | Exam- | Exam- |
|---|---|---|---|---|---|
| of test | Item | Control | ple 1 | ple 2 | ple 3 |
| Simu- | First capacitance | 0.74 | 0.684 | 0.746 | 0.729 |
| lation | Second capacitance | 0.667 | 0.615 | 0.685 | 0.658 |
| results | Capacitance difference | 0.072 | 0.068 | 0.062 | 0.071 |
| | (Second capacitance − | | | | |
| | First capacitance) | | | | |
| | Rate of change | 9.80% | 9.99% | 8.28% | 9.72% |
| | (Capacitance difference/ | | | | |
| | First capacitance) | | | | |
| Test | Touch test | OK | OK | OK | OK |
| results | | | | | |

In Table 5 above, “First capacitance” refers to the capacitance value of the touch structure when no touch action is applied thereto, or the capacitance value of the touch structure when there is no pressing or touch function is triggered; “Second capacitance” refers to the capacitance value of the touch structure 60 when the touch action is applied thereto, or the capacitance value of the touch structure when there is pressing or the touch function is triggered. In the tested results of the touch test, “OK” means that the touch function of the touch structure 60 is good and there is no abnormality.

“Rate of change” may reflect the change degree of the capacitance value of the touch structure 60 before and after the touch action is applied, and the larger the value, the better the touch performance. It can be seen from the above Table that, the solution of Example 2 may have a negative effect on the touch performance of the display panel 100, and the solution of Example 1 and the solution of Example 3 may have a little effect on the touch performance of the display panel 100. Based on this, it can be considered that, in the embodiments of the present disclosure, the effect of the change of the material of the first insulating layer 61 and/or the material of the second insulating layer 63 on the touch performance of the display panel 100 is within an acceptable range, that is, the touch performance of the display panel 100 will not be significantly reduced.

Based on the multiple simulation/test experiments above, in the embodiments of the present disclosure, although the change of the material of the first insulating layer 61 and/or the material of the second insulating layer 63 may have some negative effects on some performances of the display panel 100, the negative effects are all small and within the allowable range of the corresponding test performance. However, in the embodiments of the present disclosure, it is possible to significantly reduce the risk of peeling of the display panel 100, reduce the risk of cracks of the display panel 100, and improve the luminous efficiency of the display panel 100 to a certain degree. Based on this, the present disclosure has achieved obvious beneficial effects compared to the related art.

Some other embodiments of the present disclosure provide a display apparatus, and the display apparatus may be any apparatus that displays an image whether in motion (e.g., videos) or stationary (e.g., still images) and whether textual or graphical. For example, the display apparatus may be any product or component having a display function, such as a television, a notebook computer, a tablet computer, a mobile phone, an electronic photo, an electronic billboard or sign, a personal digital assistant (PDA), a navigator, a wearable device, an augmented reality (AR) device, a virtual reality (VR) device.

The display apparatus may be an electroluminescence display apparatus or photoluminescence display apparatus. In a case where the display apparatus is the electroluminescent display apparatus, the electroluminescent display apparatus may be an organic light-emitting diode (OLED) display apparatus or a quantum dot light-emitting diode (QLED) display apparatus. In a case where the display apparatus is the photoluminescent display apparatus, the photoluminescent display apparatus may be a quantum dot photoluminescent display apparatus.

In some embodiments, the display apparatus includes a display panel 1000 and a driving circuit board. The driving circuit board may include, for example, a timing controller (TCON), a power management chip DC/DC, an adjustable resistor voltage divider circuit (generating Vcom) and other driving circuits. The driving circuit board is electrically connected to the display panel 100 for driving the display panel 100 to display images.

The display panel 100 may be formed by cutting the display motherboard 1000 described in any of the above embodiments. That is to say, the display motherboard 1000 described in any of the above embodiments is cut to form the display panel 100 in the embodiments of the present disclosure.

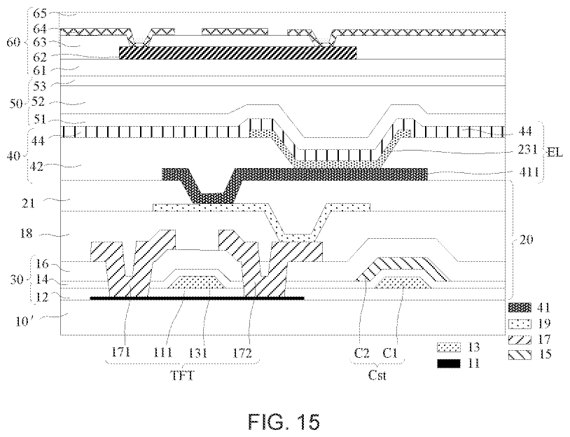

Referring to FIG. 15, the display panel 100 includes a substrate 10′, a pixel definition layer 42, a first encapsulation layer 50 and a first insulating layer 61. The substrate 10′ refers to a portion of the substrate motherboard 10 that is located in a display area AA and a peripheral area BB surrounding the display area AA after cutting. The pixel definition layer 42 is disposed on the substrate 10′, and a material of the pixel definition layer 42 includes a hydrophilic material. The first encapsulation layer 50 is disposed on a side of the pixel definition layer 42 away from the substrate 10′. The first insulating layer 61 is disposed on a side of the first encapsulation layer 50 away from the substrate 10′, and the material of the first insulating layer 61 includes a hydrophilic material. In this way, it is possible to reduce the risk of peeling and cracks during the manufacturing process of the display panel 100, and for the specific reasons, the reference will be made to the above description, and will not be repeated here.

In some embodiments, the material of the first insulating layer 61 includes silicon oxide (SiO_{X}; X≥1) and/or silicon oxynitride (SiON_{X}; X≥1). The hydrophilicity of silicon oxide and the hydrophilicity of silicon oxynitride are all greater than the hydrophilicity of silicon nitride (the material of the first insulating layer in the related art).

In a case where the display panel 100 further includes a touch structure 60, the display panel 100 further includes a first metal layer 62, a second metal layer 64 and a second encapsulation layer 65. The first metal layer 62 is located between the first insulating layer 61 and the second insulating layer 63, the second metal layer 64 is located on a side of the second insulating layer 63 away from the first encapsulation layer 50, and the second encapsulation layer 65 is located on a side of the second metal layer 64 away from the first encapsulation layer 50. The material of the second insulating layer 63 is at least one of silicon nitride, silicon oxynitride and silicon oxide.

In some embodiments, both the first insulating layer 61 and the second insulating layer 63 are of a single-layer film structure. That is, the first insulating layer 61 and the second insulating layer 63 are both formed by a single film forming process. The material of the first insulating layer 61 and the material of the second insulating layer 63 both include silicon oxynitride. Alternatively, the material of the first insulating layer 61 includes silicon oxynitride, and the material of the second insulating layer 63 includes silicon nitride. Alternatively, the material of the first insulating layer 61 includes silicon oxide, and the material of the second insulating layer 63 includes silicon nitride. Alternatively, the material of the first insulating layer 61 includes silicon oxide, and the material of the second insulating layer 63 includes silicon oxynitride.

In some implementations, in a case where the material of the first insulating layer 61 includes silicon oxynitride and the material of the second insulating layer 63 includes silicon nitride, the thickness of the first insulating layer 61 is smaller than the thickness of the second insulating layer 63 (it will be noted that, in a case where both the first insulating layer 61 and the second insulating layer 63 are made of silicon nitride, they have the same thickness). That is to say, by reducing the thickness of the first insulating layer 61 (a silicon oxynitride material layer), it is possible to reduce or even eliminate the effect on the manufacturing efficiency of the display motherboard 1000 caused by the change of the material of the first insulating layer 61.

In some embodiments, the first encapsulation layer 50 includes the first inorganic layer 51, the organic layer 52 and the second inorganic layer 53 that are stacked, the refractive index of the first insulating layer 61 is less than the refractive index of the second inorganic layer 53, and the refractive index of the second insulating layer 63 is greater than the refractive index of the first insulating layer 61. That is, the second inorganic layer 53, the first insulating layer 61, and the second insulating layer 63 are a high-refractive-index layer, a low-refractive-index layer, and a high-refractive-index layer in order. In this way, it is beneficial to improving the luminous efficiency of the display panel.

In some embodiments, the first insulating layer 61 is of a multi-layer film structure; that is to say, the first insulating layer 61 may be the sum of multiple film layers. The multi-layer films included in the first insulating layer 61 include first sub-films 611 and second sub-films 612 alternately stacked; that is, a film layer in the first insulating layer 61 closest to the substrate 10′ is the first sub-film 611. The material of the first sub-film 611 includes silicon oxide or silicon oxynitride.

In some embodiments, the material of the first sub-film 611 includes silicon oxide, and the material of the second sub-film 612 includes silicon nitride. Alternatively, the material of the first sub-film 611 includes silicon oxynitride, and the material of the second sub-film 612 includes silicon nitride. Alternatively, the material of the first sub-film 611 includes silicon oxide, and the material of the second sub-film 612 includes silicon oxynitride. In this way, it may be possible to satisfy that the refractive index of the second sub-film 612 may be greater than that of the first sub-film 611, which facilitates the formation of the micro-cavity by the first insulating layer 61 to improve the luminous efficiency of the display panel 10.

In some embodiments, the second insulating layer 63 may also be of a multi-layer film structure. The multi-layer films included in the second insulating layer 63 include third sub-films 631 and fourth sub-films 632 stacked alternately. The material of the third sub-film 631 may include silicon oxide or silicon oxynitride. In this way, the hydrophilicity of the third sub-film 631 is relatively high, which may increase the adhesive force between the third sub-film 631 and the first insulating layer 61, and reduce the risk of peeling between the second insulating layer 63 and the first insulating layer 61.

In some embodiments, the first encapsulation layer 50 includes a first inorganic layer 51, an organic layer 52 and a second inorganic layer 53 that are stacked. The refractive index of the first sub-film 611 of the first insulating layer 61 is smaller than the refractive index of the second inorganic layer 53, and the refractive index of the second sub-film 612 of the first insulating layer 61 is greater than the refractive index of the first sub-film 611 of the first insulating layer 61.

In a case where a layer in the multi-layer films included in the first insulating layer 61 farthest from the substrate 10′ is the first sub-film 611, the refractive index of the third sub-film 631 is greater than the refractive index of the first sub-film 611, and the refractive index of the fourth sub-film 632 is smaller than the refractive index of the third sub-film 631. In this way, the second inorganic layer 53, the multi-layer film structure of the first insulating layer 61 and the multi-layer film structure of the second insulating layer 63 may constitute a structure in which high-refractive index material layers and low-refractive index material layers stacked alternatively, which is conducive to improving the luminous efficiency of the display panel 100.

In a case where a film in the multi-layer films included in the first insulating layer 61 farthest from the substrate 10′ is the second sub-film 612, the refractive index of the third sub-film 631 is smaller than the refractive index of the second sub-film 612, and the refractive index of the fourth sub-film 632 is greater than the refractive index of the third sub-film 631. In this way, the second inorganic layer 53, the multi-layer film structure of the first insulating layer 61 and the multi-layer film structure of the second insulating layer 63 may constitute a structure in which high-refractive index material layers and low-refractive index material layers stacked alternatively, which is conducive to improving the luminous efficiency of the display panel 100.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display motherboard having a plurality of display areas, peripheral areas each surrounding a single display area, and a cutting area located on a side of the peripheral areas away from the respectively display areas; the display motherboard comprising:
a substrate motherboard;
virtual barriers disposed on the substrate motherboard and in the cutting area; wherein a virtual barrier includes a planarization layer block and a pixel definition layer block that are stacked, and the pixel definition layer block is farther away from the substrate motherboard than the planarization layer block;
a first encapsulation layer located in a display area and a peripheral area surrounding the display area and spaced from the virtual barriers; and
a first insulating layer disposed on a side of the first encapsulation layer away from the substrate motherboard, covering the virtual barriers, and in contact with the pixel definition layer block;
wherein a material of the pixel definition layer block and a material of the first insulating layer each include a hydrophilic material.

2. The display motherboard according to claim 1, wherein the material of the first insulating layer includes silicon oxide and/or silicon oxynitride.

3. The display motherboard according to claim 1, further comprising:
a second insulating layer disposed on a side of the first insulating layer away from the substrate motherboard, covering the virtual barriers and in contact with the first insulating layer; wherein a material of the second insulating layer includes at least one of silicon oxide, silicon oxynitride and silicon nitride.

4. The display motherboard according to claim 3, wherein both the first insulating layer and the second insulating layer are of a single-layer film structure;
both the material of the first insulating layer and the material of the second insulating layer include silicon oxynitride; or
the material of the first insulating layer includes silicon oxynitride, and the material of the second insulating layer includes silicon nitride; or
the material of the first insulating layer includes silicon oxide, and the material of the second insulating layer includes silicon nitride; or
the material of the first insulating layer includes silicon oxide, and the material of the second insulating layer includes silicon oxynitride.

5. The display motherboard according to claim 4, wherein the material of the first insulating layer includes silicon oxynitride or silicon oxide, and the material of the second insulating layer includes silicon nitride; and a thickness of the first insulating layer is less than a thickness of the second insulating layer; and/or
the first encapsulation layer includes a first inorganic layer, an organic layer and a second inorganic layer that are stacked; wherein a refractive index of the first insulating layer is smaller than a refractive index of the second inorganic layer, and a refractive index of the second insulating layer is greater than the refractive index of the first insulating layer.

6. (canceled)

7. The display motherboard according to claim 3, wherein the first insulating layer is of a multi-layer film structure; in a direction perpendicular to the substrate motherboard and away from the substrate motherboard, multi-layer films included in the first insulating layer include a first sub-film and a second sub-film alternately stacked; a material of the first sub-film includes silicon oxide or silicon oxynitride; or
the first insulating layer is of a multi-layer film structure; in a direction perpendicular to the substrate motherboard and away from the substrate motherboard, multi-layer films included in the first insulating layer include a first sub-film and a second sub-film alternately stacked; a material of the first sub-film includes silicon oxide or silicon oxynitride; wherein the material of the first sub-film includes silicon oxide, and a material of the second sub-film includes silicon nitride; or the material of the first sub-film includes silicon oxide, and the material of the second sub-film includes silicon oxynitride; or the material of the first sub-film includes silicon oxynitride, and the material of the second sub-film includes silicon nitride.

8. (canceled)

9. The display motherboard according to claim 7, wherein the second insulating layer of a multi-layer film structure;
in the direction perpendicular to the substrate motherboard and away from the substrate motherboard, multi-layer films included in the second insulating layer include a third sub-film and a fourth sub-film alternately stacked; a material of the third sub-film includes silicon oxide or silicon oxynitride.

10. The display motherboard according to claim 9, wherein a film in the multi-layer films included in the first insulating layer farthest from the substrate motherboard is the second sub-film;
the material of the third sub-film includes silicon oxide, and a material of the fourth sub-film includes silicon oxynitride or silicon nitride; or
a material of the second sub-film includes silicon nitride, the material of the third sub-film includes silicon oxynitride, and the material of the fourth sub-film includes silicon nitride.

11. The display motherboard according to claim 9, wherein the first encapsulation layer includes a first inorganic layer, an organic layer and a second inorganic layer that are stacked;
a refractive index of the first sub-film of the first insulating layer is smaller than a refractive index of the second inorganic layer, and a refractive index of the second sub-film of the first insulating layer is greater than the refractive index of the first sub-film of the first insulating layer; wherein
in a case where a film in the multi-layer films included in the first insulating layer farthest from the substrate motherboard is the first sub-film, the refractive index of the third sub-film is greater than the refractive index of the first sub-film, and the refractive index of the fourth sub-film is smaller than the refractive index of the third sub-film; and
in a case where a film in the multi-layer films included in the first insulating layer farthest from the substrate motherboard is the second sub-film, the refractive index of the third sub-film is smaller than the refractive index of the second sub-film, and the refractive index of the fourth sub-film is greater than the refractive index of the third sub-film.

12. The display motherboard according to claim 1, further comprising:
an inorganic material stacked-layer, a first planarization layer, a second planarization layer, and a pixel definition layer that are sequentially arranged in a direction perpendicular to the substrate motherboard and away from the substrate motherboard, the pixel definition layer being closer to the substrate motherboard than the first encapsulation layer;
wherein the planarization layer block includes a first sub-block disposed in the first planarization layer and a second sub-block disposed in the second planarization layer; the pixel definition layer block is disposed in the pixel definition layer; and
an orthographic projection of the second sub-block on the substrate motherboard is located within an orthographic projection of the first sub-block on the substrate motherboard, and the pixel definition layer block covers a surface of the second sub-block away from the substrate motherboard and sidewalls of the second sub-block.

13. The display motherboard according to claim 12, further comprising:
a first barrier located in the peripheral area and surrounding the display area; wherein the first barrier includes a third sub-block disposed in the second planarization layer and a fourth sub-block disposed in the pixel definition layer; an orthographic projection of the fourth sub-block on the substrate motherboard is within an orthographic projection of the third sub-block on the substrate motherboard;
a second barrier located in the peripheral area and on a side of the first barrier away from the display area; wherein the second barrier includes a fifth sub-block disposed in the first planarization layer, a sixth sub-block disposed in the second planarization layer, and a seventh sub-block disposed in the pixel definition layer; on the substrate motherboard, an orthographic projection of the seventh sub-block is located within an orthographic projection of the sixth sub-block, and the orthographic projection of the sixth sub-block is located within an orthographic projection of the fifth sub-block; and
an anti-crack barrier located in the peripheral area and on a side of the second barrier away from the first barrier, the anti-crack barrier including an eighth sub-block disposed in the first planarization layer;
wherein the inorganic material stacked-layer includes a first groove located between the virtual barriers and the peripheral area, and a second groove located between two adjacent virtual barriers;
the display motherboard further comprises:
a first connecting portion at least partially located in the first groove and connected to the eighth sub-block and the first sub-block; and
a second connecting portion at least partially located in the second groove and connected to first sub-blocks of the two adjacent virtual barriers.

14. (canceled)

15. A display panel having a display area and a peripheral area surrounding the display area, the display panel comprising:
a substrate;
a pixel definition layer disposed on the substrate, a material of the pixel definition layer including a hydrophilic material;
a first encapsulation layer disposed on a side of the pixel definition layer away from the substrate; and
a first insulating layer disposed on a side of the first encapsulation layer away from the substrate, a material of the first insulating layer including another hydrophilic material.

16. The display panel according to claim 15, wherein the material of the first insulating layer includes silicon oxide and/or silicon oxynitride.

17. The display panel according to claim 15, further comprising:
a second insulating layer disposed on a side of the first insulating layer away from the substrate, wherein a material of the second insulating layer includes at least one of silicon oxide, silicon oxynitride and silicon nitride.

18. The display panel according to claim 17, wherein both the first insulating layer and the second insulating layer are of a single-layer film structure;
both the material of the first insulating layer and the material of the second insulating layer include silicon oxynitride; or
the material of the first insulating layer includes silicon oxynitride, and the material of the second insulating layer includes silicon nitride; or
the material of the first insulating layer includes silicon oxide, and the material of the second insulating layer includes silicon oxynitride; or
the material of the first insulating layer includes silicon oxide, and the material of the second insulating layer includes silicon nitride.

19. The display panel according to claim 18, wherein the material of the first insulating layer includes silicon oxynitride or silicon oxide, and the material of the second insulating layer includes silicon nitride; and a thickness of the first insulating layer is less than a thickness of the second insulating layer; and/or
the first encapsulation layer includes a first inorganic layer, an organic layer and a second inorganic layer that are stacked; wherein a refractive index of the first insulating layer is smaller than a refractive index of the second inorganic layer, and a refractive index of the second insulating layer is greater than the refractive index of the first insulating layer.

20. (canceled)

21. The display panel according to claim 17, wherein the first insulating layer is of a multi-layer film structure; in a direction perpendicular to the substrate and away from the substrate, multi-layer films included in the first insulating layer include a first sub-film and a second sub-film alternately stacked; a material of the first sub-film includes silicon oxide or silicon oxynitride; or
the first insulating layer is of a multi-layer film structure; in a direction perpendicular to the substrate and away from the substrate, multi-layer films included in the first insulating layer include a first sub-film and a second sub-film alternately stacked; a material of the first sub-film includes silicon oxide or silicon oxynitride; wherein the material of the first sub-film includes silicon oxide, and a material of the second sub-film includes silicon nitride; or the material of the first sub-film includes silicon oxide, and the material of the second sub-film includes silicon oxynitride; or the material of the first sub-film includes silicon oxynitride, and the material of the second sub-film includes silicon nitride.

22. (canceled)

23. The display panel according to claim 21, wherein the second insulating layer of a multi-layer film structure;
in the direction perpendicular to the substrate and away from the substrate, multi-layer films included in the second insulating layer include a third sub-film and a fourth sub-film alternately stacked; a material of the third sub-film includes silicon oxide or silicon oxynitride.

24. The display panel according to claim 23, wherein a film in the multi-layer films included in the first insulating layer farthest from the substrate is the second sub-film; the material of the third sub-film includes silicon oxide, and a material of the fourth sub-film includes silicon oxynitride or silicon nitride; or the material of the second sub-film includes silicon nitride, the material of the third sub-film includes silicon oxynitride, and the material of the fourth sub-film includes silicon nitride; and/or
the first encapsulation layer includes a first inorganic layer, an organic layer and a second inorganic layer that are stacked; a refractive index of the first sub-film of the first insulating layer is smaller than a refractive index of the second inorganic layer, and a refractive index of the second sub-film of the first insulating layer is greater than the refractive index of the first sub-film of the first insulating layer in a case where a film in the multi-layer films included in the first insulating layer farthest from the substrate is the first sub-film, the refractive index of the third sub-film is greater than the refractive index of the first sub-film, and the refractive index of the fourth sub-film is smaller than the refractive index of the third sub-film; in a case where a film in the multi-layer films included in the first insulating layer farthest from the substrate is the second sub-film, the refractive index of the third sub-film is smaller than the refractive index of the second sub-film, and the refractive index of the fourth sub-film is greater than the refractive index of the third sub-film.

25. (canceled)

26. (canceled)

27. A display apparatus, comprising:
the display panel according to claim 15; and
a driving circuit board connected to the display panel.
